(19) United States
(12) Patent Application Publication
(10) Pub. No.: US 2026/0282950 A1
(43) Pub. Date: Sep. 17, 2026

(54) POWER SEMICONDUCTOR PACKAGE INCLUDING A CONTACT PIN WITH A POINTED TIP AND METHOD OF FABRICATION THEREOF

(71) Applicant: Infineon Technologies AG, Neubiberg (DE)

(72) Inventors: Alexander Schwarz, Soest (DE); Tobias Stäber, Regenstauf (DE)

(21) Appl. No.: 19/552,283

(22) Filed: Feb. 27, 2026

(30) Foreign Application Priority Data
Mar. 11, 2025 (DE) 102025109266.4

(51) Int. Cl. H10W 70/40; H10W 70/04; H10W 74/01; H10W 74/10

(52) U.S. Cl. CPC H10W 70/464; H10W 70/048; H10W 70/457; H10W 70/481; H10W 74/01; H10W 74/114

(57) ABSTRACT

A power semiconductor package includes: at least one power semiconductor die; a leadframe having load terminals and at least one contact pin connected to the power semiconductor die, the load terminals configured to carry a load current and the contact pin configured to carry a control signal or a sensing signal; and an encapsulation body encapsulating the power semiconductor die. The load terminals and the contact pin are exposed from the encapsulation body. The contact pin includes a pointed tip facing away from the power semiconductor package. The pointed tip includes a first cut surface and a second cut surface intersecting along an edge. The edge has a width measured perpendicular to a length of the edge of 3/8 or less of a thickness of the contact pin, the thickness being measured along the length of the edge.

### TECHNICAL FIELD

The present disclosure in general relates to a power semiconductor package, in particular to a power semiconductor package comprising a contact pin with a pointed tip, as well as to a method for fabricating such a power semiconductor package

### BACKGROUND

A power semiconductor package may comprise one or more power semiconductor dies encapsulated by an encapsulation body. Load terminals as well as control and/or sensing terminals may be exposed from the encapsulation body in order to provide electrical contacts to the power semiconductor die(s). Such load terminals are configured to carry a load current and such control or sensing terminals are configured to carry control or sensing signals, respectively. The control and/or sensing terminals may for example comprise contact pins configured be inserted into a socket of an external appliance like a driver board, wherein the driver board is configured to drive the power semiconductor die(s) of the power semiconductor package. Such contact pins and/or such sockets may be comparatively small and/or fragile. It may therefore be particularly important to properly align the contact pins with the sockets in order to establish proper electrical contact and/or not to damage any of the involved components. However, the required precision during fabrication of the contact pins as well as the required precision during alignment of the power semiconductor package and e.g. the driver board relative to each other may significantly increase the overall costs. Improved power semiconductor packages as well as improved methods for fabricating power semiconductor packages may help with solving these and other problems.

### SUMMARY

Various aspects pertain to a power semiconductor package, comprising: at least one power semiconductor die, a leadframe comprising load terminals and at least one contact pin connected to the power semiconductor die, the load terminals configured to carry a load current and the contact pin configured to carry a control signal or a sensing signal, and an encapsulation body encapsulating the power semiconductor die, wherein the load terminals and the contact pin are exposed from the encapsulation body, wherein the contact pin comprises a pointed tip facing away from the power semiconductor package, wherein the pointed tip comprises a first and a second cut surface intersecting along an edge, wherein the edge has a width measured perpendicular to a length of the edge of ⅜ or less of a thickness of the contact pin, the thickness being measured along the length of the edge.

Various aspects pertain to a method for fabricating a power semiconductor package, the method comprising: providing a leadframe comprising load terminals and at least one contact pin, the load terminals configured to carry a load current and the contact pin configured to carry a control signal or a sensing signal, wherein a distal end of the contact pin is connected to a frame portion of the leadframe, wherein a first lateral side of the contact pin comprises a tapering at a predefined position, the tapering comprising a first cut surface, connecting at least one power semiconductor die to the load terminals and to the contact pin, encapsulating the power semiconductor die with an encapsulation body such that the load terminals and the contact pin are exposed from the encapsulation body, and cutting through the contact pin at the predefined position to separate the contact pin from the frame portion, thereby fabricating a second cut surface and thereby forming a pointed tip facing away from the power semiconductor package, wherein the pointed tip comprises the first and the second cut surface, wherein the first and the second cut surface intersect along an edge, and wherein the edge has a width measured perpendicular to a length of the edge of ⅜ or less of a thickness of the contact pin, the thickness being measured along the length of the edge.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A to 1C schematically illustrate a power semiconductor package comprising a contact pin with a pointed tip. FIG. 1A illustrates a plan view of the power semiconductor package, FIG. 1B illustrates a sectional view of the power semiconductor package and FIG. 1C illustrates a detail view of the contact pin.

FIG. 2 illustrates a detail view of a contact pin comprising a pointed tip, the contact pin coupled to a socket of an external appliance.

FIGS. 3A to 3D schematically illustrate a contact pin in various stages of fabrication according to an exemplary method for fabricating a power semiconductor package.

FIG. 4 schematically illustrates a detail view of the pointed tip of a contact pin according to an example.

FIG. 5 schematically illustrates a perspective view of a further power semiconductor package comprising contact pins with pointed tips, wherein the contact pins comprise a bend such that the pointed tip points in another direction than the load terminals of the power semiconductor package.

FIG. 6 is a flow chart of an exemplary method for fabricating a power semiconductor package, the power semiconductor package comprising a contact pin with a pointed tip.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or,” unless expressly noted otherwise. For example, the expression “at least one of A and B” should be interpreted to mean A but not B, B but not A, or both A and B.

The examples of a power semiconductor package described below may use various types of semiconductor dies or circuits incorporated in the semiconductor dies, among them AC/DC or DC/DC converter circuits, power MOS transistors, power Schottky diodes, JFETs (Junction Gate Field Effect Transistors), power bipolar transistors, power integrated circuits, etc. The examples may also use semiconductor dies comprising MOS transistor structures or vertical transistor structures like, for example, IGBT (Insulated Gate Bipolar Transistor) structures or, in general, transistor structures in which at least one electrical contact pad is arranged on a first main face of the semiconductor die and at least one other electrical contact pad is arranged on a second main face of the semiconductor die, opposite to the first main face.

In several examples layers or layer stacks may be applied to one another or materials may be applied or deposited onto layers. It should be appreciated that any such terms as “applied” or “deposited” are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, sputtering, plating, molding, CVD, etc.

An efficient power semiconductor package and an efficient method for fabricating a power semiconductor package may for example reduce material consumption, ohmic losses, chemical waste, etc. and may thus enable energy and/or resource savings. Improved power semiconductor packages and improved methods for fabricating a power semiconductor package, as specified in this description, may thus at least indirectly contribute to green technology solutions, i.e. climate-friendly solutions providing a mitigation of energy and/or resource use.

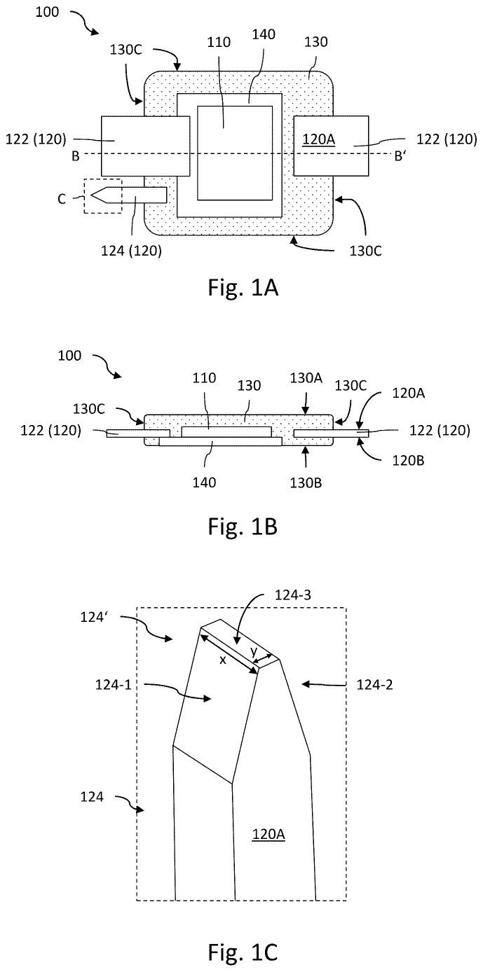

FIG. 1A schematically shows a plan view of a power semiconductor package 100 comprising at least one power semiconductor die 110, a leadframe 120 comprising load terminals 122 and at least one contact pin 124, and an encapsulation body 130. FIG. 1B shows a sectional view of the power semiconductor package 100 along the line B-B′ in FIG. 1A and FIG. 1C shows an enlarged view of the section “C” in FIG. 1A.

The power semiconductor package 100 may be a discrete package comprising a single power semiconductor die 110 or the power semiconductor package 100 may comprise a plurality of power semiconductor dies 110. In the latter case, the power semiconductor dies 110 may all be the same type of die or different types of dies. Furthermore, the power semiconductor package 100 may comprise any suitable electrical circuit realized using the power semiconductor dies 110, for example a half bridge circuit, a full bridge circuit, a converter circuit, an inverter circuit, etc.

The power semiconductor package 100 may be configured to operate with a high voltage, e.g. a voltage of 100V or more, or 500V or more, or 1.2 kV or more, or even 2 kV or more. Furthermore, the power semiconductor package 100 may be configured to operate with a strong electrical current, for example a current of 1 A or more, or 10 A or more, or even 100 A or more.

The power semiconductor package 100 may be configured for use in any suitable application, for example automotive applications, industrial applications or household applications. According to a specific example, the power semiconductor package 100 is configured for use in the main inverter of an electric engine of an electric vehicle.

The leadframe 120 comprises load terminals 122 and at least one contact pin 124. The load terminals 122 and the contact pin are electrically connected to the power semiconductor die 110. Furthermore, the load terminals 122 are configured to carry a load current and the contact pin 124 is configured to carry a control signal or a sensing signal.

The power semiconductor package 100 may further comprise a carrier 140, wherein the power semiconductor die 110 is arranged on and electrically connected to the carrier 140. According to an example, the carrier 140 may be part of the leadframe 120. In this case, at least one of the load terminals 122 and the carrier 140 may be a monolithic part. However, it is also possible that the carrier 140 is for example a substrate of the type direct bonded copper (DBC), direct bonded aluminum (DBA), active metal braze (AMB), insulated metal substrate (IMS), etc. In the latter case, one or more of the load terminals 122 possibly one or more contact pin 124 may be coupled to the carrier 140 using e.g. a solder joint, a sintered joint or a joint comprising conductive glue.

The power semiconductor die 110 may for example comprise a first side and an opposite second side, wherein the first side faces the carrier 140. A first load electrode may be arranged on the first side of the power semiconductor die 110 and a second load electrode may be arranged on the second side. The first load electrode may for example be a drain electrode or an emitter electrode and the second load electrode may be a source electrode or a collector electrode. According to another example, the positions of the first and second load electrodes are reversed. The power semiconductor die 110 may further comprise a gate electrode, which may e.g. be arranged on the second side.

A first one of the load terminals 122 may be electrically connected to the first load electrode of the power semiconductor die 110 and a second one of the load electrodes 122 may be electrically connected to the second load electrode. The contact pin 124 may for example be connected to the gate electrode. However, the power semiconductor package 100 may also comprise a contact pin 124 that is connected to the first load electrode or to the second load electrode or to a temperature sensor.

The leadframe 120 may have any suitable thickness measured between a first side 120A and an opposite second side 120B. For example, the thickness may be in the range of about 0.3 mm to about 3 mm. The lower limit of this range may also be about 0.5 mm, or about 0.8 mm, or about 1 mm and the upper limit may also be about 2.5 mm, or about 2 mm, or about 1.5 mm, or about 1.2 mm.

The leadframe 120 may comprise or consist of any suitable metal or metal alloy. For example, the leadframe 120 may comprise or consist of Al or Cu. According to an example, the leadframe 120 is plated, for example with a plating comprising or consisting of Ni and/or Sn (in particular, those parts of the leadframe 120 that are exposed from the encapsulation body 130 may be plated). According to another example, the leadframe 120 is not plated.

The encapsulation body 130 encapsulates the power semiconductor die 110. The encapsulation body 130 may comprise a first side 130A, an opposite second side 130B and lateral sides 130C connecting the first and second sides 130A, 130B. The encapsulation body 130 may for example comprise or consist of a molded body. A molded body may for example be fabricated using a process like compression molding, injection molding or transfer molding. The molded body may comprise inorganic filler particles configured to reduce the thermal resistance of the molded body. According to another example, the encapsulation body 130 comprises a plastic frame surrounding an interior volume at least partially filled with a suitable potting material.

The first side 130A of the encapsulation body 130 may for example be configured to face a driver board configured to drive the power semiconductor die(s) 110. The second side 130B of the encapsulation body 130 may be configured to be arranged on a substrate like, for example, a heatsink. According to an example, the carrier 140 may be exposed from the second side 130B of the encapsulation body 130 in order to provide a heat dissipation pathway at the second side 130B. It is also possible that the first side 130A as well is configured to be coupled to a heatsink. To this end, the power semiconductor package 100 may comprise a second carrier exposed from the first side 130A, wherein the power semiconductor die 110 is arranged between the carriers and thermally connected to both of the carriers.

The load terminals 122 and the contact pin 124 are exposed from the encapsulation body 130. For example, the load terminals 122 may be exposed from one or more of the lateral sides 130C of the encapsulation body 130, in particular from opposite ones of the lateral sides 130C. The one or more contact pins 124 may also be exposed from one or more of the lateral sides 130C of the encapsulation body 130. According to an example, the one or more contact pins 124 are exposed from a single one of the lateral sides 130C, in particular from a lateral side 130C from which also at least one load terminal 122 is exposed. According to an example, no load terminals 122 and/or no contact pins 124 are exposed from the first side 130A and/or from the second side 130B of the encapsulation body 130.

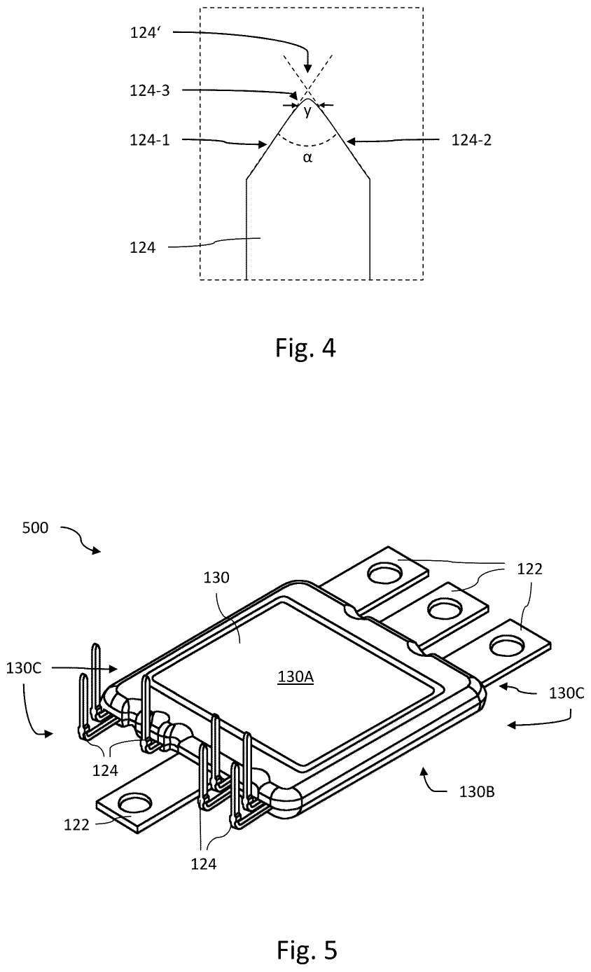

In the example shown in FIG. 1A, the contact pin 124 and the load terminals 122 are arranged in a common plane. However, it is also possible that the contact pin 124 comprises a bend such that an outer portion of the contact pin 124 is bent out of the plane. In this case, the contact pin 124 may in particular comprise a bend of about or exactly 90°, such that the outer portion is perpendicular to the first side 130A of the molded body 130 (see, e.g., FIG. 5). This may allow connecting the contact pin 124 to a driver board that is arranged above the first side 130A.

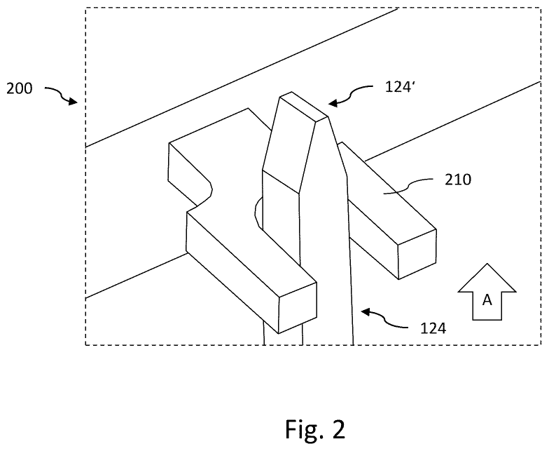

The load terminals 122 may for example be configured to be coupled to an external appliance, e.g. busbars by welding, soldering and/or screwing. The contact pin 124 may for example be configured to be coupled to an external appliance like a driver board by insertion into a socket and possibly by an additional soldering process (see, e.g., FIG. 2).

As shown in FIG. 1C, the contact pin 124 comprises a pointed tip 124′ facing away from the power semiconductor package 100. The pointed tip 124′ comprises a first cut surface 124-1 and a second cut surface 124-2, wherein the first and the second cut surface 124-1, 124-2 intersect along an edge 124-3. The edge 124-3 has a length x (which may be equal to the thickness of the leadframe 110) and a width y which is measured perpendicular to the length x. An ideal pointed tip 124′ would have zero width, i.e. the edge of an ideal pointed tip 124′ would be perfectly sharp. Realistically however, the width y of the edge 124-3 is non-zero. The width y in particular is ⅜ (three eighth) or less of the thickness of the contact pin (or the length x).

FIG. 2 shows the contact pin 124 coupled to an external appliance 200, e.g. a driver board. The external appliance 200 comprises a socket 210, wherein the contact pin 124 is inserted into the socket 210, thereby electrically connecting the contact pin 124 to the external appliance 200.

In the example shown in FIG. 2, the socket 210 essentially consists of a fork, wherein the contact pin 124 is inserted between the prongs of the fork. However, the socket 210 may have any other suitable shape and may for example comprise a through hole extending through the external appliance 200. The socket 210 may comprise or consist of any suitable metal or metal alloy and may for example comprise or consist of Al or Cu.

According to an example, a solder joint or a joint comprising glue may be formed between the socket 210 and the contact pin 124 in order to improve the mechanical stability and/or the electrical characteristics of the joint between the contact pin 124 and the socket 210. However, this does not have to be the case. In the case that a glued joint is used, the glue may be electrically conductive or electrically insulating (in the latter case, the contact pin 124 has to be in direct contact with the socket 210).

The contact pin 124 may be inserted into the socket 210 along the longitudinal axis of the contact pin 124, i.e. along the arrow “A” in FIG. 2. Inserting the contact pin 124 into the socket 210 comprises aligning the power semiconductor package 100 with the external appliance 200. Positioning tolerances and/or manufacturing tolerances may cause the contact pin 124 and the socket 210 to be (slightly) misaligned with respect to each other. However, the pointed tip 124′ may help with correctly inserting the contact pin 124 into the socket. A sharper pointed tip 124′ may be more able to assist in correcting a misalignment than a less sharp pointed tip 124′ (a dull tip may simply bump against an edge of the socket 210 without being able to steer the contact pin 124 into the socket 210 like a sharp tip would be).

For this reason, it may be desirable to fabricate the contact pin 124 with a particularly sharp pointed tip 124′, that is, the width y of the edge 124-3 should be as small as possible. However, according to design rules for conventional leadframe structuring, a ratio between the contours and the thickness of a leadframe is about 1:1. Using conventional means to fabricate the contact pin 124 would therefore result in a tip that would not be sharp enough to guide the tip into the socket 210 in a reliable manner.

In particular, a conventional fabrication process for contact pins may comprise providing a leadframe, punching opposite lateral sides of a lead of the leadframe at a predefined position in order to fabricate a constriction and subsequently punching through the lead at the constriction in order to fabricate a contact pin with a tip. The final punching process is conventionally performed such that the cut surface is perpendicular to a longitudinal extension of the contact pin, resulting in a comparably dull tip.

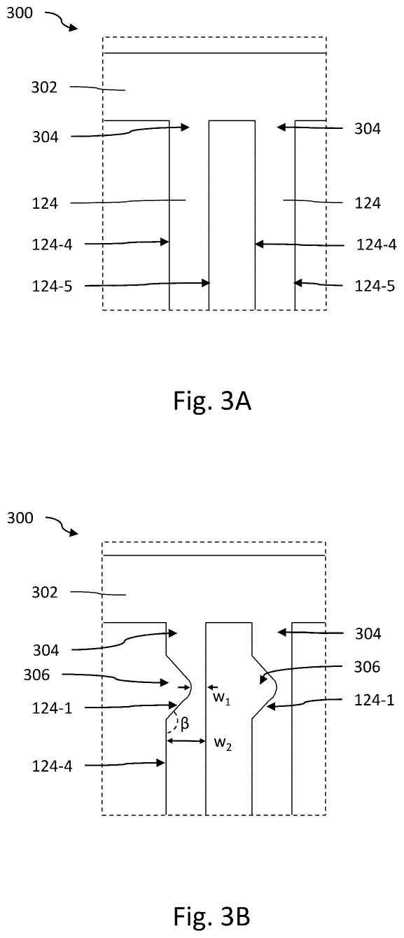

FIGS. 3A to 3D show an exemplary process of fabricating the contact pin 124 with the pointed tip 124′.

FIG. 3A shows a detail view of a leadframe 300 comprising a frame portion 302 and contact pins 124 connected to the frame 302. The leadframe 300 may correspond to the leadframe 120 of FIGS. 1A-1C. According to an example, distal ends 304 of the contact pins 124 are connected to the frame portion 302. Opposite second distal ends of the contact pins 124 (not shown) may for example be connected to another portion of the leadframe 300. Each contact pin 124 comprises a first lateral side 124-4 and an opposite second lateral side 124-5, such that opposing ones of the lateral sides 124-4, 124-5 of adjacent contact pins 124 face each other. The leadframe 300 furthermore comprises additional parts that are not shown in FIGS. 3A-3D, for example the load terminals 122.

As shown in FIG. 3B, a tapering 306 is fabricated at a predefined position of the first lateral side 124-4 of the contact pin(s) 124. The tapering 306 comprises the first cut surface 124-1.

Fabricating the tapering 306 may for example comprise punching or stamping the leadframe 300. The direction of the punch may be perpendicular to the drawing plane. As shown in FIG. 3B, the contact pins 124 are still connected to the frame portion 302 when the tapering 306 is fabricated. In this manner, fabricating the tapering 306 cannot lead to displacement of the contact pins 124. Furthermore, it is possible to subject the leadframe 300, including the contact pin(s) 124 to a plating process (e.g. an electroplating process) after the fabrication of the tapering 306 (because there is still an electrical pathway along the contact pin(s) 124).

The tapering 306 may have any suitable first width w₁, measured at the most narrow point of the tapering 306 and the contact pin 124 may have any suitable second width w₂, measured outside of the tapering 306. For example, the first width w₁ may for example be in the range of about one fifth of w₂ to about four fifth of w₂. The lower limit of this range may also be about one quarter of w₂, or about one third of w₂ and the upper limit may also be about two thirds of w₂ or about one half of w₂. According to an example, the second width w2 may be about equal to the thickness of the leadframe 300.

The tapering 306 may have any suitable shape as viewed from above the leadframe 300. For example, the tapering 306 may have an essentially triangular shape. A point of the triangular shape may be rounded due to limitations of the punching process (see, e.g., FIG. 3B). Note that the first cut surface 124-1 and the first lateral side 124-1 may intersect at an angle β of more than 90°, for example more than 110°, or more than 130° in order to fabricate the pointed tip 124′.

According to an example, material of the contact pin 124 is punched away only at one of the lateral sides 124-4, 124-5 in order to fabricate the tapering 306 (see, e.g., FIG. 3B). However, it is also possible that material is punched away at both of the lateral sides 124-4, 124-5 at this stage of the fabrication process.

According to an example, the one or more power semiconductor dies 110 are connected to the load terminals 122 and to the contact pin(s) 124 of the leadframe 300 in the stage of the fabrication process of a power semiconductor package shown in FIG. 3B. In the case that the leadframe 300 does not comprise a die pad, this may for example also comprise providing the carrier 140. Furthermore, the encapsulation body 130 may be fabricated in this stage of the fabrication process.

FIG. 3C shows a process of cutting through the contact pin 124 at the predefined position in order to separate the contact pin 124 from the frame portion 302. According to an example, this cutting comprises a punching process or a stamping process. In FIG. 3C, the line A-A′ indicate the cutting line along which the contact pins 124 is cut. Note that the cutting line A-A′ and the longitudinal axis a of the contact pin 124 intersect at an angle of less than 90°, for example less than 70° or even less than 50° in order to fabricate a sharp pointed tip 124′ of the contact pin 124. According to an example, the cutting line A-A′ and the first cut surface 124-1 intersect the longitudinal axis “a” at an identical or nearly identical angle, however, this does not necessarily have to be the case.

With the cutting process shown in FIG. 3C, the second cut surface 124-2 is fabricated and the pointed tip 124′ is formed (see, e.g., FIG. 3D).

As noted further above, the leadframe 300 may be subjected to a plating process prior to cutting away the frame portion 302. In this case, the first cut surface 124-1 may be a plated surface and the second cut surface 124-2 is a non-plated surface. It is however also possible that the plating process is performed prior to fabricating the tapering 306. In this case, neither the first cut surface 124-1 nor the second cut surface 124-2 are plated surfaces and only the remaining surfaces of the contact pin 124 are plated.

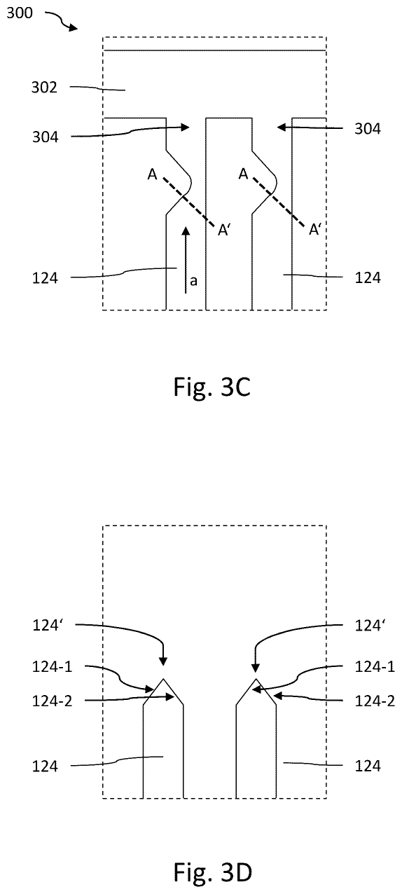

FIG. 4 shows a detail view of the pointed tip 124′ of a contact pin 124 according to an example.

In the example shown in FIG. 4, the pointed tip 124′ has a rounded edge 124-3 and not an essentially flat edge 124-3 as shown in the example of FIG. 1C. In this case, the width y of the edge 124-3 may be defined to equal two times the radius of curvature of the rounded edge 124-3.

As shown in FIG. 4, the first cut surface 124-1 and the second cut surface 124-2 intersect each other at an angle of intersection α. According to an example, the angle of intersection α is in the range of about 20° to about 50°. The lower limit of this range may also be about 25° or about 30° and the upper limit may also be about 45° or about 40°. A smaller angle of intersection α may mean having a sharper pointed tip 124′. However, the pointed tip 124′ may become too thin and therefore too fragile if α becomes too small. The value for α may therefore be a compromise between sharpness, which enables the pointed tip 124′ to guide the contact pin 124 into a socket, and mechanical stability.

FIG. 5 shows a perspective view of a further power semiconductor package 500, which may be similar or identical to the power semiconductor package 100, except for the differences described in the following.

As shown in FIG. 5, the power semiconductor package 500 may for example comprise more than one contact pin 124. The power semiconductor package 500 may for example comprise a half bridge circuit. In the example shown in FIG. 5, the contact pins 124 are exposed from a first one of the lateral sides 130C of the encapsulation body 130. The load terminals 122 are exposed from the first one of the lateral sides 130C and also from an opposite second one of the lateral sides 130C of the encapsulation body 130. According to the depicted example, the first and second sides 130A, 130B of the encapsulation body 130 are free of any load terminals 122 or contact pins 124.

The load terminal 122 exposed from the first one of the lateral sides 130C may for example be a phase current terminal and the load terminals 122 exposed from the second one of the lateral sides 130C may for example comprise at least one DC+terminal and at least one DC-terminal.

As shown in FIG. 5, each contact pin 124 comprises a bend outside of the encapsulation body 130, such that the pointed tip 124′ points in a different direction than a base portion of the respective contact pin 124, wherein the base portion is the portion inside the encapsulation body 130 and immediately bordering the encapsulation body 130. The base portion may essentially have the same orientation as the load terminals 122.

According to an example, each contact pin 124 may essentially comprise a 90° bend, such that the pointed tip 124′ is arranged perpendicular to the first side 130A of the encapsulation body 130 (and perpendicular to the base portion). In this manner, the contact pin 124 can be connected to an external application arranged above the first side 130A.

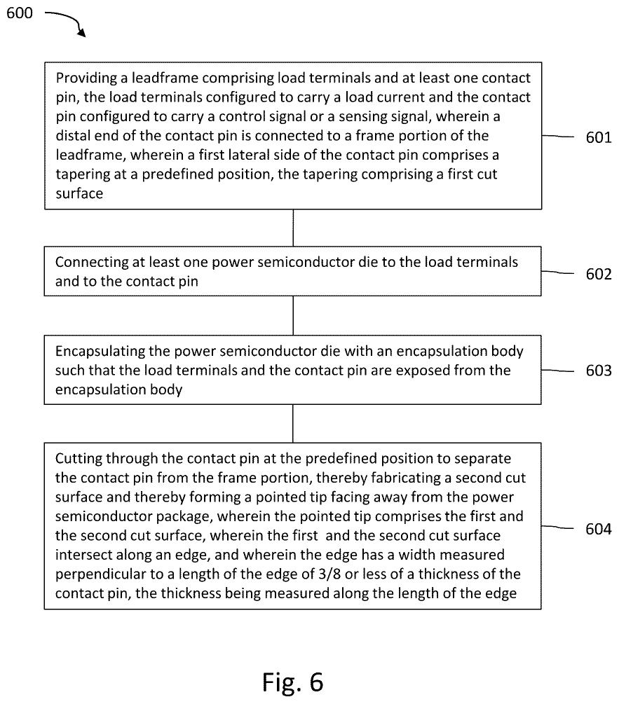

FIG. 6 is a flow chart of an exemplary method 600 for fabricating a power semiconductor package. The method 600 may for example be used to fabricate the power semiconductor package 100 or 500. The method 600 may for example comprise processes as described with respect to FIGS. 3A-3D.

The method 600 comprises at 601 a process of providing a leadframe comprising load terminals and at least one contact pin, the load terminals configured to carry a load current and the contact pin configured to carry a control signal or a sensing signal, wherein a distal end of the contact pin is connected to a frame portion of the leadframe, wherein a first lateral side of the contact pin comprises a tapering at a predefined position, the tapering comprising a first cut surface; at 602 a process of connecting at least one power semiconductor die to the load terminals and to the contact pin; at 603 a process of encapsulating the power semiconductor die with an encapsulation body such that the load terminals and the contact pin are exposed from the encapsulation body; and at 604 a process of cutting through the contact pin at the predefined position to separate the contact pin from the frame portion, thereby fabricating a second cut surface and thereby forming a pointed tip facing away from the power semiconductor package, wherein the pointed tip comprises the first and the second cut surface, wherein the first and the second cut surface intersect along an edge, and wherein the edge has a width measured perpendicular to a length of the edge of ⅜ or less of a thickness of the contact pin, the thickness being measured along the length of the edge.

According to an example, the method 600 may optionally comprise a process of plating over the leadframe after the encapsulation body has been formed during the process 603. The plating process may in particular be performed prior to the cutting process at 604.

According to an example, the method 600 further comprises a process of bending the contact pin outside of the encapsulation body. This bending process may, for example, comprise stamping the leadframe. The bending process and the cutting process at 604 may be a common process or the bending process may be a subsequent process to the cutting process at 604. The bending process and/or the cutting process at 604 may be part of a trim and form process performed onto the leadframe, i.e. the contact pin and the load terminals.

In the following, the power semiconductor package and the method for fabricating a power semiconductor package are further explained using specific examples.

Example 1 is a power semiconductor package, comprising: at least one power semiconductor die, a leadframe comprising load terminals and at least one contact pin connected to the power semiconductor die, the load terminals configured to carry a load current and the contact pin configured to carry a control signal or a sensing signal, and an encapsulation body encapsulating the power semiconductor die, wherein the load terminals and the contact pin are exposed from the encapsulation body, wherein the contact pin comprises a pointed tip facing away from the power semiconductor package, wherein the pointed tip comprises a first and a second cut surface intersecting along an edge, wherein the edge has a width measured perpendicular to a length of the edge of ⅜ or less of a thickness of the contact pin, the thickness being measured along the length of the edge.

Example 2 is the power semiconductor package of example 1, wherein an angle of intersection between the first and the second cut surface is in the range of 20° to 50°, in particular in the range of 30° to 45°.

Example 3 is the power semiconductor package of example 1 or 2, wherein the second cut surface is free of any plating and the first cut surface and any remaining surfaces of the contact pin exposed from the encapsulation body are covered by a plating.

Example 4 is the power semiconductor package of example 3, wherein the plating comprises or consists of Ni and/or Sn.

Example 5 is the power semiconductor package of one of the preceding examples, wherein the contact pin has a thickness in the range of 0.5 mm to 2 mm, in particular in the range of 0.7 mm to 1.2 mm.

Example 6 is the power semiconductor package of one of the preceding examples, wherein a width of the contact pin measured outside of the pointed tip and perpendicular to the thickness is in the range of 0.5 mm to 2 mm, in particular in the range of 0.7 mm to 1.2 mm.

Example 7 is the power semiconductor package of one of the preceding examples, wherein the encapsulation body comprises a first side, an opposite second side and lateral sides connecting the first and second sides, and wherein the contact pin and the load terminals are exposed from one or more of the lateral sides of the encapsulation body.

Example 8 is the power semiconductor package of example 7, wherein the contact pin comprises a bend outside of the encapsulation body such that the tip points in a direction that is perpendicular to the first side of the encapsulation body.

Example 9 is the power semiconductor package of example 7 or 8, wherein the first and second sides of the encapsulation body are free of any load terminals and contact pins.

Example 10 is a method for fabricating a power semiconductor package, the method comprising: providing a leadframe comprising load terminals and at least one contact pin, the load terminals configured to carry a load current and the contact pin configured to carry a control signal or a sensing signal, wherein a distal end of the contact pin is connected to a frame portion of the leadframe, wherein a first lateral side of the contact pin comprises a tapering at a predefined position, the tapering comprising a first cut surface, connecting at least one power semiconductor die to the load terminals and to the contact pin, encapsulating the power semiconductor die with an encapsulation body such that the load terminals and the contact pin are exposed from the encapsulation body, and cutting through the contact pin at the predefined position to separate the contact pin from the frame portion, thereby fabricating a second cut surface and thereby forming a pointed tip facing away from the power semiconductor package, wherein the pointed tip comprises the first and the second cut surface, wherein the first and the second cut surface intersect along an edge, and wherein the edge has a width measured perpendicular to a length of the edge of ⅜ or less of a thickness of the contact pin, the thickness being measured along the length of the edge.

Example 11 is the method of example 10, further comprising: plating over the leadframe after the encapsulation body has been formed.

Example 12 is the method of example 11, wherein the leadframe is platted prior to cutting through the contact pin.

Example 13 is the method of one of examples 10 to 12, wherein an angle of intersection between the first and the second cut surface is in the range of 20° to 50°, in particular in the range of 30° to 45°.

Example 14 is the method of one of examples 10 to 13, further comprising: bending the contact pin outside of the encapsulation body.

Example 15 is the method of example 14, wherein the contact pin is bent such that the pointed tip points in a direction that is perpendicular to the load terminals.

Example 16 is the method of one of examples 10 to 15, wherein the encapsulation body comprises a first side, an opposite second side and lateral sides connecting the first and second sides, and wherein the contact pin and the load terminals are exposed from one or more of the lateral sides of the encapsulation body.

Example 17 is an apparatus comprising means for performing the method according to anyone of examples 10 to 16.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor package, comprising:
at least one power semiconductor die;
a leadframe comprising a plurality of load terminals and at least one contact pin connected to the power semiconductor die, the load terminals configured to carry a load current and the contact pin configured to carry a control signal or a sensing signal; and
an encapsulation body encapsulating the power semiconductor die,
wherein the load terminals and the contact pin are exposed from the encapsulation body,
wherein the contact pin comprises a pointed tip facing away from the power semiconductor package,
wherein the pointed tip comprises a first cut surface and a second cut surface intersecting along an edge,
wherein the edge has a width measured perpendicular to a length of the edge of ⅜ or less of a thickness of the contact pin, the thickness being measured along the length of the edge.

2. The power semiconductor package of claim 1, wherein an angle of intersection between the first cut surface and the second cut surface is in a range of 20° to 50°.

3. The power semiconductor package of claim 2, wherein the angle is in a range of 30° to 45°.

4. The power semiconductor package of claim 1, wherein the second cut surface is free of any plating, and wherein the first cut surface and any remaining surfaces of the contact pin exposed from the encapsulation body are covered by a plating.

5. The power semiconductor package of claim 4, wherein the plating comprises Ni and/or Sn.

6. The power semiconductor package of claim 1, wherein the thickness of the contact pin is in a range of 0.5 mm to 2 mm.

7. The power semiconductor package of claim 6, wherein the thickness of the contact pin is in a range of 0.7 mm to 1.2 mm.

8. The power semiconductor package of claim 1, wherein a width of the contact pin measured outside of the pointed tip and perpendicular to the thickness of the contact pin is in a range of 0.5 mm to 2 mm.

9. The power semiconductor package of claim 8, wherein the width of the contact pin is in a range of 0.7 mm to 1.2 mm.

10. The power semiconductor package of claim 1, wherein the encapsulation body comprises a first side, an opposite second side, and a plurality of lateral sides connecting the first and second sides, and wherein the contact pin and the load terminals are exposed from one or more of the lateral sides of the encapsulation body.

11. The power semiconductor package of claim 10, wherein the contact pin comprises a bend outside of the encapsulation body such that the tip points in a direction that is perpendicular to the first side of the encapsulation body.

12. The power semiconductor package of claim 10, wherein the first and second sides of the encapsulation body are free of any load terminals and contact pins.

13. A method for fabricating a power semiconductor package, the method comprising:
providing a leadframe comprising a plurality of load terminals and at least one contact pin, the load terminals configured to carry a load current and the contact pin configured to carry a control signal or a sensing signal, wherein a distal end of the contact pin is connected to a frame portion of the leadframe, wherein a first lateral side of the contact pin comprises a tapering at a predefined position, the tapering comprising a first cut surface;
connecting at least one power semiconductor die to the load terminals and to the contact pin;
encapsulating the power semiconductor die with an encapsulation body such that the load terminals and the contact pin are exposed from the encapsulation body; and
cutting through the contact pin at the predefined position to separate the contact pin from the frame portion, thereby fabricating a second cut surface and thereby forming a pointed tip facing away from the power semiconductor package,
wherein the pointed tip comprises the first cut surface and the second cut surface,
wherein the first cut surface and the second cut surface intersect along an edge, and
wherein the edge has a width measured perpendicular to a length of the edge of ⅜ or less of a thickness of the contact pin, the thickness being measured along the length of the edge.

14. The method of claim 13, further comprising:
after the encapsulation body is formed, plating over the leadframe.

15. The method of claim 14, wherein the plating occurs prior to the cutting.

16. The method of claim 13, wherein an angle of intersection between the first cut surface and the second cut surface is in a range of 20° to 50°.

17. The method of claim 16, wherein the angle is in a range of 30° to 45°.

18. The method of claim 13, further comprising:
bending the contact pin outside of the encapsulation body.

19. The method of claim 18, wherein the contact pin is bent such that the pointed tip points in a direction that is perpendicular to the load terminals.

20. The method of claim 13, wherein the encapsulation body comprises a first side, an opposite second side, and a plurality of lateral sides connecting the first and second sides, and wherein the contact pin and the load terminals are exposed from one or more of the lateral sides of the encapsulation body.
